(19) United States
(12) Patent Application Publication
(10) Pub. No.: US 2014/0004700 A1
(43) Pub. Date: Jan. 2, 2014

(54) MANUFACTURING METHOD FOR A SEMICONDUCTOR APPARATUS

(71) Applicant: CANON KABUSHIKI KAISHA, Tokyo (JP)

(72) Inventor: Yasushi Nakata, Yokohama-shi (JP)

(21) Appl. No.: 13/925,510

(22) Filed: Jun. 24, 2013

(30) Foreign Application Priority Data
Jun. 27, 2012 (JP) 2012-144326

(51) Int. Cl. H01L 21/768

(52) U.S. Cl. CPC H01L 21/768
USPC 438/688

(57) ABSTRACT

A manufacturing method includes forming a wiring layer including a first wiring connected to a gate electrode of a semiconductor element, a second wiring having an area in an orthogonal projection onto a plane including a surface of the semiconductor substrate larger than the first wiring, and a third wiring connected to a protective element, from a conductive material film by etching using plasma on the conductive material film. In the forming the wiring layer, the etching is conducted in a manner that a part that becomes the first wiring of the conductive material film is separated from the part that becomes the second wiring of the conductive material film earlier than a part that becomes the third wiring of the conductive material film.

### BACKGROUND OF THE INVENTION

1. Field of the Invention

The present disclosure relates to a manufacturing method for a semiconductor apparatus.

2. Description of the Related Art

A method of forming a wiring of a semiconductor apparatus includes a method of patterning a conductive material film by plasma etching. According to this method, the wiring may be charged by the plasma etching in some cases. If the wiring is charged, a potential at a gate electrode of a MOS transistor connected to the relevant wiring changes, and a large electric field is applied to a gate insulating film, so that the gate insulating film may be damaged.

To cope with this problem, Japanese Patent Laid-Open No. 11-074523 discloses a technology of providing a dummy wiring on a semiconductor substrate. In a process of forming the wiring, electric carriers accumulated in the wiring connected to the gate electrode are discharged to the semiconductor substrate via the dummy wiring to reduce the damage on the gate insulating film.

In addition, to cope with this problem, Japanese Patent Laid-Open No. 2001-210716 discloses a technology of replacing a wiring having an area exceeding a predetermined area with plural wirings having an area lower than or equal to the predetermined area and electrically connecting the plural wirings to each other via wirings or plugs on another layer.

However, according to Japanese Patent Laid-Open No. 11-074523, a detailed investigation has not been made with regard to an area of the wiring connected to the gate electrode. In a case where the area of the wiring connected to the gate electrode is large, when the wiring is formed from the conductive material film, the gate insulating film may be damaged by the electric carriers accumulated in the conductive material film.

According to Japanese Patent Laid-Open No. 2001-210716, since the plural wirings are connected to each other via the wiring or the plug on the other layer, concerns about an increase in parasitic capacitance and an increase in connection resistance arise.

### SUMMARY OF THE INVENTION

A manufacturing method for a semiconductor apparatus according to the present disclosure includes: preparing a semiconductor substrate having a gate insulating film, a gate electrode provided on the gate insulating film, a protective element, and a conductive material film provided above the gate insulating film, the gate electrode, and the protective element; and forming a wiring layer including a first wiring connected to the gate electrode, a second wiring having an area in an orthogonal projection onto a plane including a surface of the semiconductor substrate larger than the first wiring, and a third wiring connected to the protective element, from the conductive material film by etching using plasma on the conductive material film, in which the etching is conducted to separate a part that becomes the first wiring of the conductive material film from a part that becomes the second wiring of the conductive material film earlier than a part that becomes the third wiring of the conductive material film in the forming the wiring layer.

Further features of the present invention will become apparent from the following description of exemplary embodiments with reference to the attached drawings.

### BRIEF DESCRIPTION OF THE DRAWINGS

FIG. 1A is a schematic cross-sectional view for describing a semiconductor apparatus according to a first exemplary embodiment.

FIG. 1B is a schematic plan view for describing the semiconductor apparatus according to the first exemplary embodiment.

FIGS. 2A to 2D are schematic cross-sectional views for describing a manufacturing method for the semiconductor apparatus according to the first exemplary embodiment.

FIGS. 3A to 3C are schematic cross-sectional views for describing the manufacturing method for the semiconductor apparatus according to the first exemplary embodiment.

FIGS. 4A to 4D are schematic plan views for describing the semiconductor apparatus according to modified examples.

FIGS. 5A and 5B are schematic cross-sectional views for describing a semiconductor apparatus according to a second exemplary embodiment.

### DESCRIPTION OF THE EMBODIMENTS

With a manufacturing method for a semiconductor apparatus according to the present disclosure, a first wiring, a second wiring, and a third wiring are formed from a conductive material film by etching using plasma. The first wiring is a wiring connected to a gate electrode of a semiconductor element. The second wiring is a wiring having an area in an orthogonal projection onto a plane including a surface of a semiconductor substrate larger than the first wiring. The third wiring is a wiring connected to a protective element. In the process of forming the wiring, a part that becomes the first wiring of the conductive material film is separated from a part that becomes the second wiring of the conductive material film earlier than a part that becomes the third wiring of the conductive material film. According to this manufacturing method, it is possible to reduce a damage on a gate insulating film while an increase in wiring capacitance is decreased.

### First Exemplary Embodiment

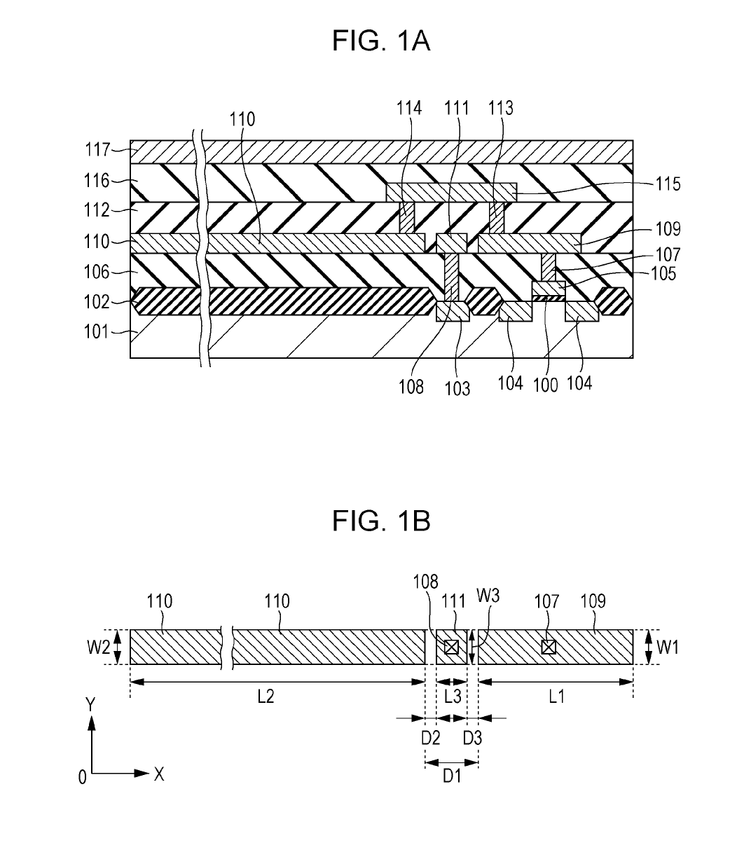

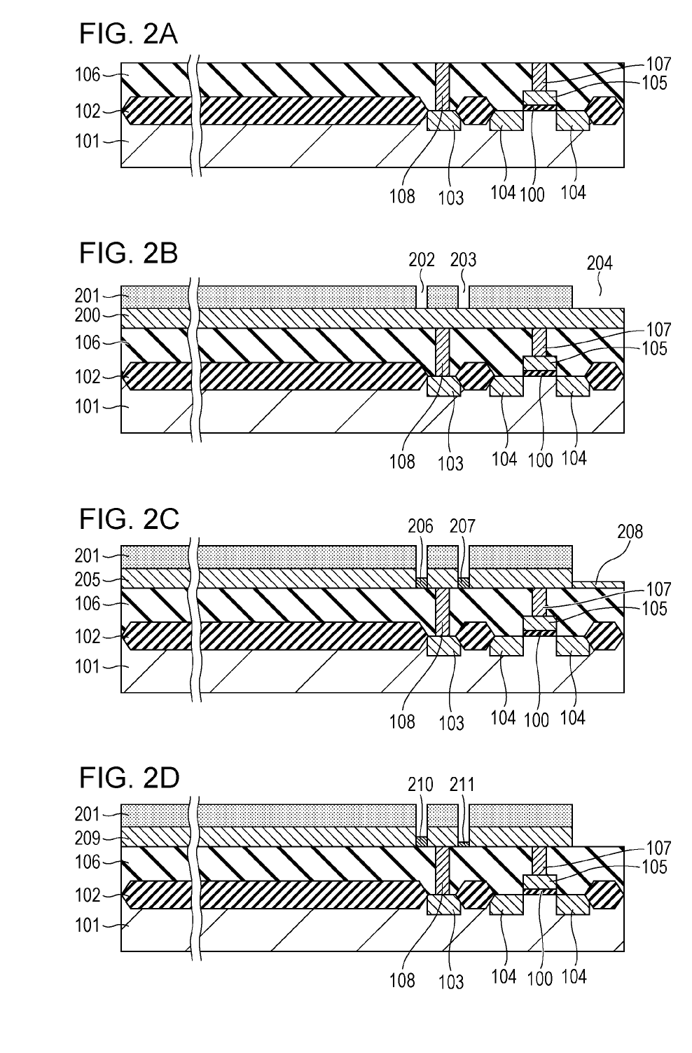

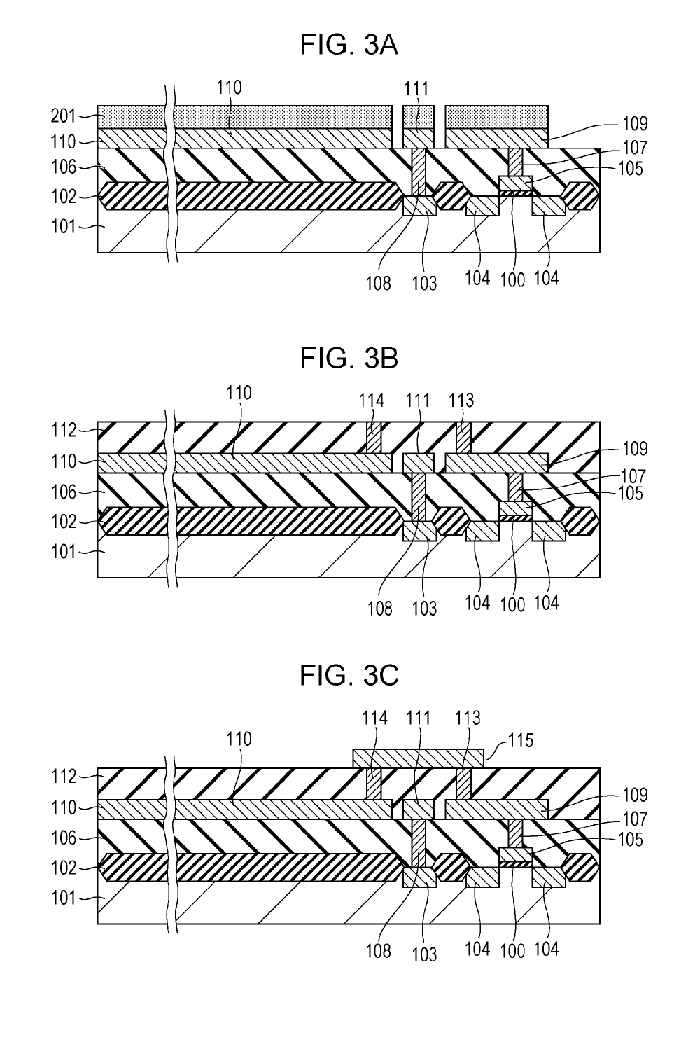

A manufacturing method for the semiconductor apparatus according to the present exemplary embodiment will be described by using FIG. 1A, FIG. 1B, FIGS. 2A to 2D, and FIGS. 3A to 3C. First, a semiconductor apparatus according to the present exemplary embodiment will be described by using FIG. 1A and FIG. 1B.

FIG. 1A is a schematic cross-sectional view of a semiconductor apparatus according to the present exemplary embodiment. In FIG. 1A, the semiconductor substrate 101 is an N-type silicon semiconductor substrate. An element isolation portion 102 including an insulator made of silicon oxide is provided to the semiconductor substrate 101. A semiconductor element is formed on a portion other than the element isolation portion 102 on a front surface side of the semiconductor substrate 101, and a semiconductor region 103 of an N-type and a source region 104 and a drain region 104 of a MOS transistor of a P-type are provided. A gate insulating film 100 is provided on a surface of the semiconductor substrate 101, and a gate electrode 105 is provided on the gate insulating film 100. The gate insulating film 100 is made of silicon oxide, and the gate electrode 105 is made of polysilicon.

An insulating film 106 is provided so as to cover the thus structured semiconductor substrate 101. Openings are prepared in the insulating film 106, and a first plug 107 and a second plug 108 which are contact plugs are provided in the opening. A first wiring layer is provided on the insulating film 106, the first plug 107, and the second plug 108. The first wiring layer includes plural wirings including a first wiring 109, a second wiring 110, and a third wiring 111. The first wiring 109, the second wiring 110, and the third wiring 111 are mutually separated by the insulating film 106 and an insulating film 112 covering the first wiring layer. Openings are prepared in the insulating film 112, and a third plug 113 and a fourth plug 114 which are via plugs are provided in the openings. A second wiring layer is provided on the insulating film 106, the third plug 113, and the fourth plug 114. The second wiring layer includes plural wirings including a fourth wiring 115 and other wirings (not illustrated). An insulating film 116 and a protective film 117 are provided on the second wiring layer.

According to the present exemplary embodiment, the insulating film 106 is made of boron-doped phosphosilicate glass (BPSG). The insulating film 112 and the insulating film 116 are made of silicon oxide. The first plug 107, the second plug 108, the third plug 113, and the fourth plug 114 include a conductor containing tungsten as a main component. These plugs may also include a conductor functioning as a barrier metal such as, for example, a titanium layer. The first wiring layer and the second wiring layer include a conductor containing aluminum as a main component. The wiring layers of these wiring layer may also include a conductor functioning as a barrier metal such as, for example, a titanium layer. The protective film 117 is made of silicon nitride.

The first plug 107 herein is connected to the gate electrode 105 of the MOS transistor and is connected to the first wiring 109. To elaborate, the gate electrode 105 is electrically connected to the first wiring 109 via the first plug 107. The second plug 108 is connected to the semiconductor region 103 and is connected to the third wiring 111. To elaborate, the semiconductor region 103 is electrically connected to the third wiring 111 via the second plug 108. The first wiring 109 and the second wiring 110 are electrically connected to each other via the third plug 113, the fourth plug 114, and the fourth wiring 115.

The semiconductor region 103 herein has a same conductive type as the semiconductor substrate 101 and electrically connects the third wiring 111 to the semiconductor substrate 101 to function as a protective element according to the present disclosure. The protective element has a function of discharging electric carriers to the semiconductor substrate 101 and may be a simple semiconductor region as in the present exemplary embodiment, and also, for example, a diode includes the semiconductor substrate 101 and a semiconductor region of an opposite conductive type, an element including a gate insulating film and a gate electrode, an ESD element, and the like can be exemplified.

FIG. 1B is a schematic plan view for describing the arrangement of the first plug 107, the second plug 108, and the wiring of the first wiring layer of FIG. 1A. FIG. 1B may be regarded as a view of projecting outer edges of the respective components onto a plane parallel to the surface of the semiconductor substrate 101 (orthogonal projection view). The first wiring 109, the second wiring 110, and the third wiring 111 are provided along a first direction X. According to the present exemplary embodiment, the wiring lengths of the respective wirings are lengths along the first direction X, and the wiring widths of the respective wirings are lengths along a second direction Y orthogonal to the first direction X. Herein, a relationship of the wiring length the wiring width is established.

The first wiring 109 connected to the first plug 107 has a wiring length L1 and a wiring width W1. The second wiring 110 electrically connected to the first wiring 109 has a wiring length L2 and a wiring width W2. The third wiring 111 connected to the second plug 108 has a wiring length L3 and a wiring width W3. The respective wirings are rectangular and include a first side and a second side according to the present exemplary embodiment. A length of the first side is the wiring length, and a length of the second side is the wiring width. Herein, the wiring width W1, the wiring width W2, and the wiring width W3 are substantially equal to each other, and the wiring length L1 is shorter than the wiring length L2 (L1<L2). To elaborate, the second wiring 110 has an area larger than the first wiring 109. The wiring length L2 is, for example, 15 mm or longer. With these wirings, it is possible to reduce the damage on the gate insulating film 100 caused by plasma at the time of manufacturing which will be described below.

According to the present exemplary embodiment, as illustrated in FIG. 1B, a distance between the first wiring 109 and the second wiring 110 is set as a distance D1, a distance between the first wiring 110 and the third wiring 111 is set as a distance D2, and a distance between the first wiring 109 and the third wiring 111 is set as a distance D3. The distance refers to a shortest distance between the wiring and the other wiring. The distance D1 is larger than the distance D2 (D1>D2). The distance D2 is smaller than the distance D3 (D2<D3). With these distance relationships, it is facilitated to discharge the electric carriers accumulated in the second wiring 110 to the semiconductor region 103, that is, the protective element instead of the gate electrode 105. Therefore, it is possible to reduce the damage on the gate insulating film 100.

According to the present exemplary embodiment, as illustrated in FIG. 1B, the third wiring 111 is provided between the first wiring 109 and the second wiring 110. With this configuration too, it is facilitated to discharge the electric carriers accumulated in the second wiring 110 to the semiconductor region 103 instead of the gate electrode 105. Furthermore, a line segment connecting the first plug 107 to the second plug 108 on a plane parallel to the surface of the semiconductor substrate 101 is preferably along the first direction X. With this configuration, it is facilitated to discharge the electric carriers accumulated in the second wiring 110 to the semiconductor region 103 instead of the gate electrode 105.

Since the third wiring 111 connected to the protective element is provided in addition to the second wiring 110, and the first wiring 109 and the second wiring 110 are separated from each other, it is possible to suppress the increase in capacitance of the second wiring 110 as compared with a case in which a connecting portion with the protective element is provided on the second wiring 110.

A manufacturing method for the semiconductor apparatus according to the present exemplary embodiment will be described by using FIGS. 2A to 2D and FIGS. 3A to 3C. These drawings are schematic cross-sectional views for describing steps of the manufacturing method for the semiconductor apparatus according to the present exemplary embodiment. The respective drawings correspond to FIG. 1A. The same configuration is assigned with the same reference sign, and a description thereof will be omitted.

First, the semiconductor substrate 101 having the structure illustrated in FIG. 2A is prepared. Since this configuration can be formed by a general semiconductor process, a description of a detailed manufacturing method will be omitted. In FIG. 2A, the element isolation portion 102 is formed by a local oxidation of silicon (LOCOS) method. However, the element isolation portion 102 can be formed by an arbitrary method such as shallow trench isolation (STI) method or a separation by a semiconductor area.

In FIG. 2B, a conductive material film 200 is formed so as to cover the first plug 107, the second plug 108, and the insulating film 106. A mask 201 is then formed on the conductive material film 200. The conductive material film 200 is a film obtained by layering titanium, aluminum, and titanium from the insulating film 106 side and is formed by a spattering method. The mask 201 is including, for example, photoresist.

The mask 201 has an arbitrary pattern and openings 202, 203, and 204. The openings include not only a so-called closed loop shape but also a slit shape and the like. Herein, the description will be given while widths of the plural openings in a depth direction of the drawing are equal to each other. An area of the opening 203 is larger than an area of the opening 202. An area of the opening 204 is larger than an area of the opening 203. The photoresist remains at a part that becomes a wiring on the mask 201 when the wiring described by using FIG. 1B is to be formed. The mask 201 has a first part covering a part that becomes a first wiring of the conductive material film, a second part covering a part that becomes a second wiring of the conductive material film, and a third part covering a part that becomes a third wiring of the conductive material film. The mask 201 is preferably formed so that a distance between the first part and the second part is larger than a distance between the second part and the third part.

The conductive material film 200 is removed by etching using the mask 201 to form the first wiring layer. This etching is conducted by using plasma such as a reactive ion etching (RIE) method. Ethylene gas (C₂H₄) is uses as etching gas for etching condition. A pressure is set in a range higher than or equal to 8 mTorr and lower than or equal to 10 mTorr. Source power is set in a range higher than or equal to 1000 W and lower than or equal to 1500 W. Bias power is set in a range higher than or equal to 100 W and lower than or equal to 200 W. Chlorine-based gas such as Cl₂, BCl₃, or CCl₄ can also be used as the etching gas.

FIG. 2C, FIG. 2D, and FIG. 3A schematically illustrate a time-lapse change of the etching. As illustrated in FIG. 2C and FIG. 2D, with regard to the condition of the etching according to the present exemplary embodiment, as the area of the region to be etched is smaller, it is more difficult for the region to be etched. To elaborate, rates at which the conductive material film 200 is removed is increased in the stated order of the opening 202, the opening 203, and the opening 204.

First, at a time point of FIG. 2C, a part of the conductive material film 200 is removed to establish a state of a conductive material film 205. The conductive material film 205 has an etched part 206, a part 207, and a part 208. Thicknesses of these parts are decreased in the stated order of the part 206, the part 207, and the part 208. Subsequently, at a time point of FIG. 2D, a further part of the conductive material film 205 is removed to establish a state of a conductive material film 209. The conductive material film 209 has an etched part 210 and a part 211. Subsequently, the part 211 is thinner than the part 210. All the conductive material at the part 208 is removed. Finally, the parts corresponding to the opening 202, the opening 203, and the opening 204 of the conductive material film 200 are removed to form the first wiring layer including the first wiring 109, the second wiring 110, and the third wiring 111 of FIG. 3A.

After the mask 201 is removed, the insulating film 112 including silicon oxide is formed by plasma CVD method (Chemical Vapor Deposition method), and the third plug 113 and the fourth plug 114 are formed (FIG. 3B). At this time, since the first wiring 109 and the second wiring 110 are separated from each other, the influence on the gate insulating film 100 is smaller than the influence caused by the plasma at the time of the etching process on the conductive material even when plasma is used for forming the insulating film 112.

Subsequently, the second wiring layer covering the insulating film 112, the third plug 113, and the fourth plug 114 is formed. The second wiring layer includes at least the fourth wiring 115. After that, the insulating film 116 and the protective film 117 are formed while covering the fourth wiring 115, so that the semiconductor apparatus illustrated in FIG. 1A is completed. In a case where the semiconductor apparatus is a solid state image pickup apparatus, a structure such as a color filter or a micro lens may also be formed thereafter. Although a description will be omitted, it may be obvious that the semiconductor apparatus includes a component such as an electrode pad for exchanging signals with an external component.

With the manufacturing method according to the present exemplary embodiment, in the process where the first wiring layer is formed from the conductive material film 200, the first wiring 109 is first separated from the second wiring 110, the third wiring 111 is separated at the last with the second wiring 110. To elaborate, first, the first wiring 109 connected to the gate electrode 105 is separated from parts that become the other wirings. With this manufacturing method, since the first wiring 109 connected to the gate electrode 105 can be separated in an early stage from the second wiring 110 having the large area applied with the plasma and easily charged, it is possible to reduce the damage on the gate electrode 105 caused by the plasma.

According to the present exemplary embodiment, the third wiring 111 is provided between the first wiring 109 and the second wiring 110, but the configuration is not limited to the above. It suffices if at least the distance D1 between the first wiring 109 and the second wiring 110 is larger than between the first wiring 109 and the third wiring 111. With the manufacturing method according to the present exemplary embodiment, the conductive material film 200 between the part that becomes the first wiring and the part that becomes the second wiring is removed earlier than the conductive material film 200 between the part that becomes the first wiring and the part that becomes the third wiring. Therefore, the first wiring 109 can be separated from the part that becomes the second wiring 110 earlier than the third wiring 111.

With regard to the etching condition, according to the present exemplary embodiment, an etching rate is higher as the area of the opening is larger. However, in the other cases too, it suffices if the first wiring can be separated from the second wiring earlier than the third wiring. To elaborate, in a case where the etching rate is higher as the area of the etching region is larger, it suffices if D1>D2 is satisfied as the relationship. At this time, D1>D3>D2 is more preferably satisfied as the relationship. In a case where the etching rate is lower as the area of the etching area is larger, it suffices if D1<D2 is satisfied as the relationship, and D2>D3>D1 is more preferably satisfied as the relationship.

According to the present exemplary embodiment, the semiconductor region 103 to which the third wiring 111 is connected has a same conductive type as the semiconductor substrate 101 and a same potential as the semiconductor substrate 101 (same node). However, the semiconductor region 103 may be an opposite conductivity type to constitute the diode with the semiconductor substrate 101 and may be in an electrically floating state. The semiconductor region 103 may be the semiconductor substrate 101 itself and may adopt any form so long as the electric carriers can be discharged to the semiconductor substrate. The wiring length L3 of the third wiring 111 may take an arbitrary value. The transistor according to the present exemplary embodiment is a type of a metal insulator semiconductor (MIS) structure. Materials of the respective components are not limited to the materials of the present exemplary embodiment.

The semiconductor apparatus according to the present exemplary embodiment includes, for example, an image pickup apparatus having image pickup region where plural photoelectric conversion elements are arranged. The first wiring 109 and the second wiring 110 according to the present exemplary embodiment may be applied to driving wirings or signal transmission wirings provided along a long side of the image pickup area of the pickup apparatus.

The plural third wirings 111 may be provided. It is possible to reduce the damage on the gate insulating film 100 more reliably by providing the plural third wirings 111. The second wiring 110 herein may be electrically connected to the semiconductor substrate via a plug or connected to another wiring.

### MODIFIED EXAMPLES

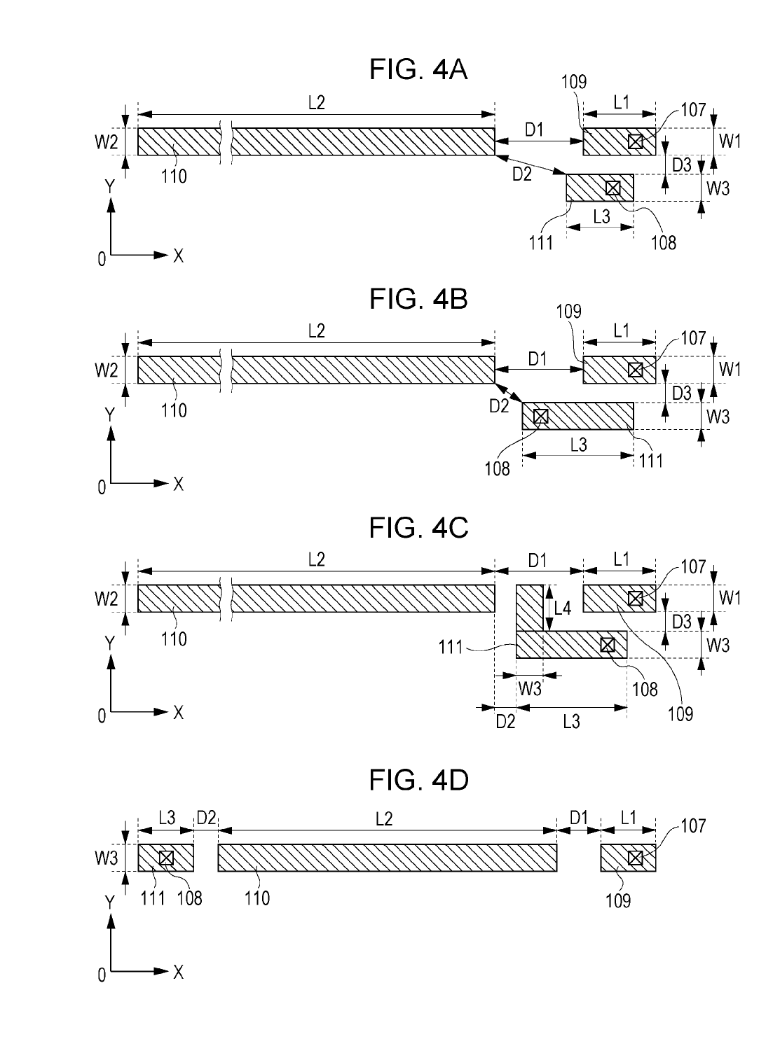

Modified examples of the arrangement of the first wiring layer according to the first exemplary embodiment will be described by using FIGS. 4A to 4D. FIGS. 4A to 4D illustrate different modified examples. FIGS. 4A to 4D are schematic plan views corresponding to FIG. 1B. The same components are assigned with the same reference signs, and a description thereof will be omitted.

In FIG. 4A, the third wiring 111 is not provided between the first wiring 109 and the second wiring 110 as is different from FIG. 1B. In FIG. 4A, the distance D1, the distance D2, and the distance D3 have a relationship of D1>D2>D3.

In FIG. 4B, the third wiring 111 is not provided between the first wiring 109 and the second wiring 110 as is different from FIG. 1B. In FIG. 4B too, the distance D1, the distance D2, and the distance D3 have a relationship of D1>D2>D3. The wiring length L3 of the third wiring 111 is longer than the wiring length L1 of the first wiring 109.

In FIG. 4C, the third wiring 111 is L-shaped, and at least a part of the third wiring 111 is provided between the first wiring 109 and the second wiring 110 similarly as in FIG. 1B. The distance D1, the distance D2, and the distance D3 herein have a relationship of D1>D2=D3.

In FIG. 4D, the third wiring 111 is not provided between the first wiring 109 and the second wiring 110, and the second wiring 110 is provided between the first wiring 109 and the third wiring 111 as is different from FIG. 1B. The distance D1 and the distance D2 herein have a relationship of D1>D2.

With the above-mentioned configuration too, since the first wiring 109 is separated from the second wiring 110 having the large area, it is possible to reduce the damage on the gate insulating film 100. It is noted that according to this modified example too, the part that becomes the first wiring 109 and the part that becomes the third wiring 111 may be separated from the part that becomes the second wiring 110 at the same time similarly as in the first exemplary embodiment.

### Second Exemplary Embodiment

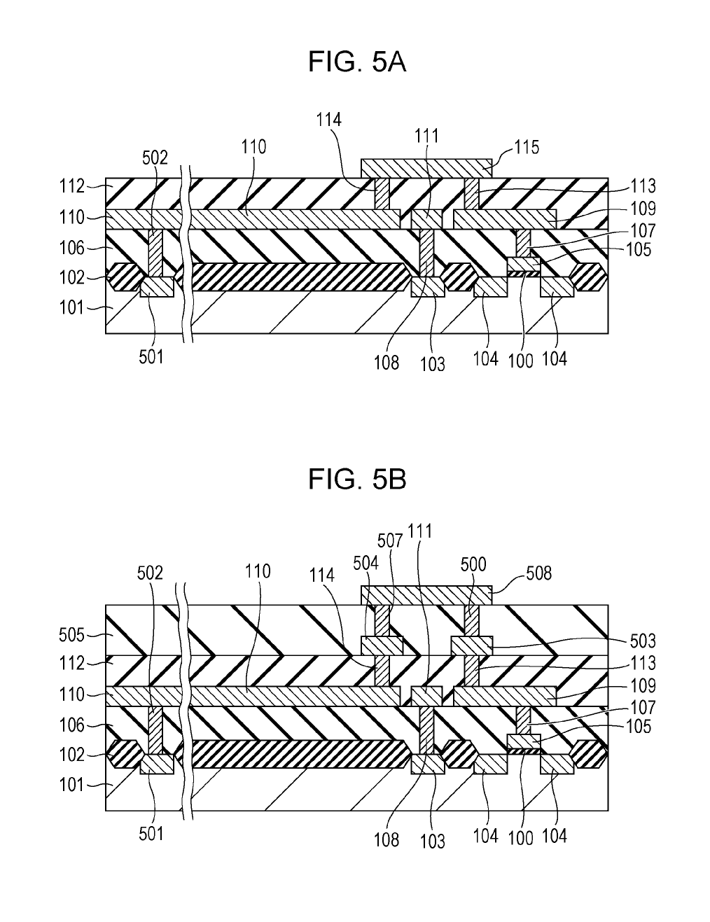

The semiconductor apparatus according to the present exemplary embodiment will be described by using FIG. 5A and FIG. 5B. According to the present exemplary embodiment, a configuration differs from the configuration according to the first exemplary embodiment in that the second wiring 110 is connected to another semiconductor region 501. The same configurations as those of FIG. 1A according to the first exemplary embodiment are assigned with the same reference signs, and a description thereof will be omitted.

As illustrated in FIG. 5A, in the semiconductor apparatus according to the present exemplary embodiment, a fifth plug 502 connected to the semiconductor region 501 is provided, and the fifth plug 502 is connected to the second wiring 110. The semiconductor region 501 is, for example, a P-type semiconductor region forms the diode with the semiconductor substrate 101. In a case where the second wiring 110 is charged, at a point where an arbitrary potential is obtained, the electric carriers are discharged from the P-type semiconductor region to the semiconductor substrate 101. With the above-mentioned configuration, the capacitance of the second wiring 110 is increased as compared with the first exemplary embodiment, but it is possible to reduce the damage on the gate insulating film 100.

FIG. 5B is a modified example of FIG. 5A. With the semiconductor apparatus illustrated in FIG. 5B, the first wiring 109 and the second wiring 110 are connected to each other by using a fifth wiring 503, a sixth wiring 504, a sixth plug 506, a seventh plug 507, and a seventh wiring 508. The fifth wiring 503 and the sixth wiring 504 are the second wiring layer, and the seventh wiring 508 is the third wiring layer. An insulating film 505 is provided between the second wiring layer and the third wiring layer. Any configuration may be adopted for the connection between the first wiring 109 and the second wiring 110, but fewer wirings and plugs are preferably used.

The components, materials, and manufacturing methods described according to the respective embodiments are examples and are not limited to the above. The respective embodiments and the modified examples can appropriately be combined with each other and can also appropriately be altered. Any width, distance, and the like according to the respective embodiments may be used so long as those are satisfied at least in a design stage.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2012-144326, filed Jun. 27, 2012, which is hereby incorporated by reference herein in its entirety.

What is claimed is:

1. A manufacturing method for a semiconductor apparatus, the method comprising:
preparing a semiconductor substrate having a gate insulating film, a gate electrode provided on the gate insulating film, a protective element, and a conductive material film provided above the gate insulating film, the gate electrode, and the protective element; and
forming a wiring layer including a first wiring connected to the gate electrode, a second wiring having an area in an orthogonal projection onto a plane including a surface of the semiconductor substrate larger than the first wiring, and a third wiring connected to the protective element, from the conductive material film by etching using plasma on the conductive material film,
wherein the etching is conducted to separate a part that becomes the first wiring of the conductive material film from a part that becomes the second wiring of the conductive material film earlier than a part that becomes the third wiring of the conductive material film in the forming the wiring layer.

2. The manufacturing method for the semiconductor apparatus according to claim 1,
wherein the forming the wiring layer includes forming the first wiring, the second wiring, and the third wiring in a manner that a distance between the second wiring and the third wiring is smaller than a distance between the first wiring and the second wiring.

3. The manufacturing method for the semiconductor apparatus according to claim 1,
wherein at least a part of the third wiring is formed between the first wiring and the second wiring.

4. The manufacturing method for the semiconductor apparatus according to claim 1,
wherein the forming the wiring layer includes forming a mask having a first part covering the part that becomes the first wiring, a second part covering the part that becomes the second wiring, and a third part covering the part that becomes the third wiring, and
wherein the first part, the second part, and the third part are formed in a manner that a distance between the third part and the second part is larger than a distance between the first part and the third part.

5. The manufacturing method for the semiconductor apparatus according to claim 1,
wherein the forming the wiring layer includes forming a mask having a first part covering the part that becomes the first wiring, a second part covering the part that becomes the second wiring, and a third part covering the part that becomes the third wiring, and
wherein the first part, the second part, and the third part are formed in a manner that a distance between the second part and the third part is smaller than a distance between the first part and the second part.

6. The manufacturing method for the semiconductor apparatus according to claim 1,
wherein the first wiring, the second wiring, and the third wiring are formed along a first direction.

7. The manufacturing method for the semiconductor apparatus according to claim 6,
wherein the first wiring and the third wiring are formed in a manner that a line segment that connects a connecting portion between the third wiring and the protective element to a connecting portion between the first wiring and the gate electrode is along the first direction.

8. The manufacturing method for the semiconductor apparatus according to claim 1,
wherein the conductive material film contains aluminum as a main component.

9. The manufacturing method for the semiconductor apparatus according to claim 1,
wherein the gate electrode and the gate insulating film constitutes a MOS transistor.

10. The manufacturing method for the semiconductor apparatus according to claim 1,
wherein the protective element is a diode.

11. The manufacturing method for the semiconductor apparatus according to claim 1,
wherein the protective element has another gate electrode different from the gate electrode and another gate insulating film different from the gate insulating film.

12. The manufacturing method for the semiconductor apparatus according to claim 1, further comprising:
forming an insulating film covering the first wiring, the second wiring, and the third wiring by a CVD method using plasma.

13. The manufacturing method for the semiconductor apparatus according to claim 12, further comprising:
forming a fourth wiring that is provided on the insulating film and connects the first wiring to the second wiring.

14. The manufacturing method for the semiconductor apparatus according to claim 1,
wherein another protective element different from the protective element is connected to the second wiring.
